(19) United States
(12) Patent Application Publication
(10) Pub. No.: US 2009/0011561 A1
(43) Pub. Date: Jan. 8, 2009

(54) Method of fabricating high-voltage mos having doubled-diffused drain

(75) Inventor: Min-Liang Chen, Hsinchu (TW)

Correspondence Address: Joe McKinney Muncy, PO Box 1364, Fairfax, VA, 22038-1364, US

(73) Assignee: ProMOS Technologies Inc.

(21) Appl. No.: 11/902,314

(22) Filed: Sep. 20, 2007

(30) Foreign Application Priority Data
Jul. 2, 2007 (TW) 96124022

(51) Int. Cl. H01L 21/336

(52) U.S. Cl. 438/275; 438/305; 257/E21.409

(57) ABSTRACT

A method of fabricating high-voltage MOS having double-diffused drain (DDD) is disclosed. The original photoresist used to define a gate is used to define double-diffused drains without increasing the complexity of the whole process. A dielectric layer and a conductive layer are sequentially formed on a substrate. A patterned photoresist is then formed on the conductive layer and then used to etch the conductive layer and the dielectric layer to form a gate and a gate dielectric layer, respectively. After stabilizing the photoresist layer, a first ion implantation is performed to form lightly doped region having deep junction. The photoresist is removed and two spacers are formed on the sidewalls of the gate. Next, a second ion implantation is performed to form heavily doped region in the substrate on outer side of the spacers.

### CROSS-REFERENCE TO RELATED APPLICATION

This application claims the priority benefit of Taiwan application serial no. 96124022, filed Jul. 2, 2007, the full disclosure of which is incorporated herein by reference.

### BACKGROUND

1. Field of Invention

The present invention relates to a method of fabricating a semiconductor device. More particularly, the present invention relates to fabricating a high-voltage MOS having double diffused drain (DDD).

2. Description of Related Art

For a high voltage metal-oxide-semiconductor (MOS) having double-diffused drain (DDD), metal silicide is usually used to fabricate gate or source/drain thereof to endure high voltage and high-speed operation. However, the breakdown voltage of the junction between the source/drain and the substrate needs to be further increased. Thus, the junction depth of the DDD needs to be further increased, too.

Conventional DDD having deep junction depth can be made by the following three methods. First, a self-aligned high-energy ions implantation through polysilicon gate is used to form the DDD having deep junction depth. However, high-energy ions penetrating the polysilicon gate and the gate oxide layer thereunder can damage the gate oxide layer and then unstablize threshold voltage.

If a hard mask layer on the polysilicon gate is used as the implantation mask for the high-energy ions implantation, the gate oxide can be protected from being damaged by high-energy ions. However, the hard mask layer needs to be removed before metal silicide is formed on the polysilicon gate. Since the material of the hard mask layer is usually silicon oxide or silicon nitride, the removal of the hard mask layer often causes damage on shallow trench isolation, and the operation of integrated circuit is thus affected.

If a mask layer, other than the polysilicon gate, is used as the implantation mask for high-energy ions implantation, and the gate oxide layer and the polysilicon gate are then formed later, the tolerable alignment error between the hard mask layer and the polysilicon gate will be crucial for further minimizing semiconductor critical dimension.

### SUMMARY

According to an embodiment of this invention, a method of fabricating a high-voltage MOS having double-diffused drain is provided.

A dielectric layer, a conductive layer and a patterned photoresist are sequentially formed on a substrate. The exposed conductive layer and the dielectric layer thereunder are etched to form a gate and a gate dielectric layer on the substrate. The structure of the photoresist is then stabilized. Lightly-doped regions having deep junctions in the substrate are formed by using the gate as an implantation mask to implant the substrate. Next, the photoresist is removed. Spacers are then formed on sidewalls of the gate. Heavily-doped regions are formed in the substrate by using the gate and the spacers as implantation masks to implant the substrate. The junction depth of the heavily-doped regions is shallower than the junction depth of the lightly-doped regions, and the dopant concentration in the heavily-doped regions is larger than the dopant concentration in the lightly-doped regions.

According to another embodiment of this invention, an integration method of fabricating low-voltage MOS and high-voltage MOS having double-diffused drain is provided.

A dielectric layer and a conductive layer are sequentially formed on a substrate having a low-voltage area and a high-voltage area. At least two first photoresists are formed on the conductive layer. Then, the exposed conductive layer and the dielectric layer thereunder are etched to respectively form a first gate and a first gate dielectric layer on the low-voltage area and a second gate and a second dielectric layer on the high-voltage area. The structure of the first photoresists are stabilized. A patterned second photoresist is formed on the low-voltage area. The high-voltage area of the substrate is implanted to form two lightly-doped regions having deep junction depth on two sides of the second gate. The second photoresist is then removed. The substrate is implanted to form lightly-doped drains on two sides of the first gate. The first photoresists are removed. Plural spacers are formed on sidewalls of the first gate and the second gate. The substrate is implanted to form source and drain on outer sides of the spacers.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1A-1D are cross-sectional diagrams showing an integration method of fabricating low-voltage MOS and high-voltage MOS having double-diffused drain according to an embodiment of this invention.

### DETAILED DESCRIPTION

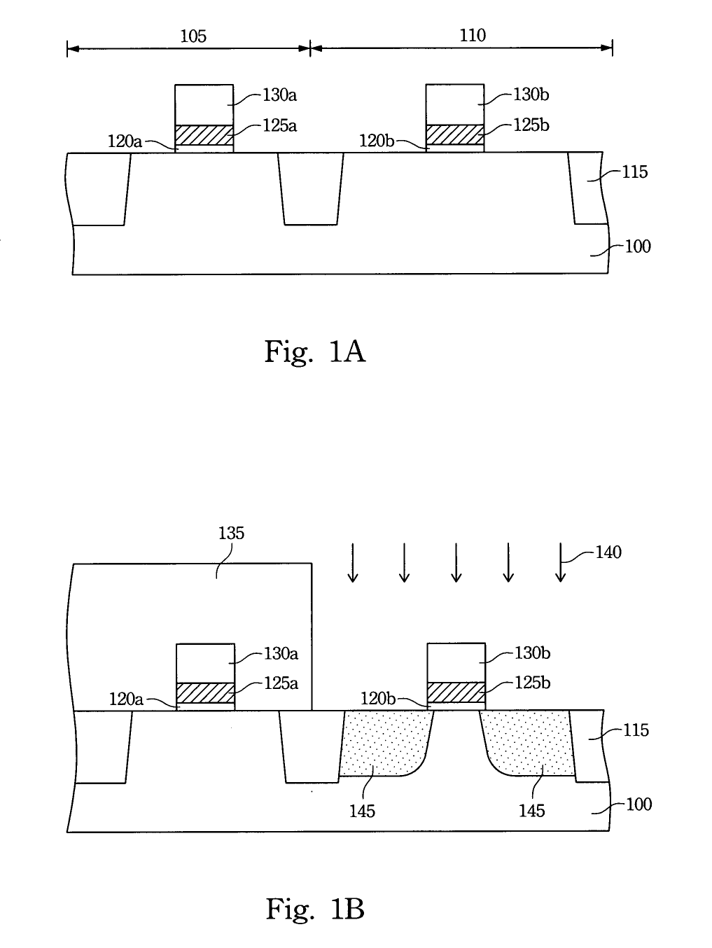

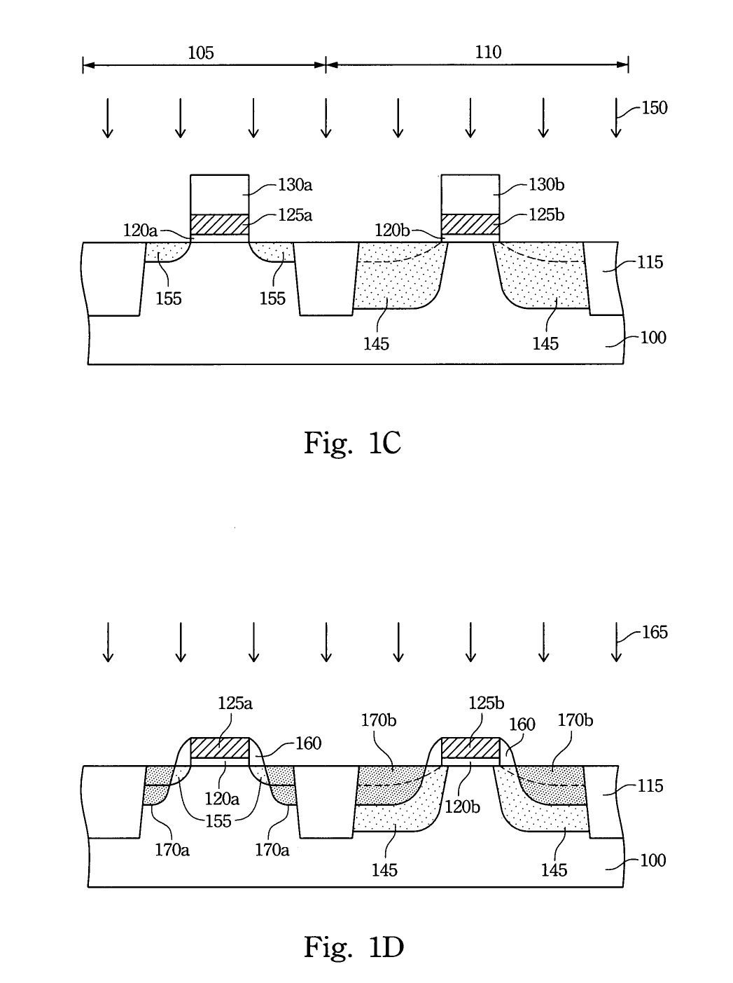

Please refer to FIGS. 1A-1D. FIGS. 1A-1D are cross-sectional diagrams showing an integration method of fabricating low-voltage MOS and high-voltage MOS having double-diffused drain according to an embodiment of this invention.

In FIG. 1A, a substrate 100 has a low-voltage area 105, a high-voltage area 110, and shallow trench isolations 115 used to define an active area. A dielectric layer and a conductive layer, such as a polysilicon layer or a metal silicide layer, are sequentially formed on the substrate 100. First photoresists 130a and 130b are formed on the conductive layer. The exposed conductive layer and the dielectric layer thereunder are etched by using the first photoresists 130a and 130b as etching masks to respectively form a first gate 125a and a first dielectric layer 120a on the low-voltage area 105 and a second gate 125b and a second dielectric layer 120b on the high-voltage area 110.

Next, the structure of the first photoresists 130a and 130b are stabilized. According to an embodiment of this invention, the thickness of the first photoresists 130a and 130b is larger than 8000 Å. The method of stabilizing the first photoresists 130a and 130b can be, for example, heating (e.g. heated under a temperature of about 200° C.) or UV illuminating to hard bake the first photoresists 130a and 130b.

In FIG. 1B, a patterned second photoresist 135 is formed on the low-voltage area 105. A first ion implantation 140 is performed to implant the high-voltage area 110 of the substrate 100 to form two lightly-doped regions 145 having deep junction depth on two sides of the second gate 125b.

In FIG. 1C, the second photoresist 135 is then removed. A second ion implantation 150 is performed to implant the substrate 100 to form lightly-doped drains 155 on two sides of the first gate 125a on low-voltage area 105.

In FIG. 1D, the first photoresists 130a and 130b are removed. Plural spacers 160 are formed on sidewalls of the first gate 125a and the second gate 125b. A third ion implantation 165 is performed to implant the substrate 100 to form source/drain 170a and 170b on outer sides of the spacers 160.

The first ion implantation 140 has the highest implantation energy, and the second ion implantation 150 has the smallest implantation energy. The first photoresists 130a, 130b and the second photoresist 135 can be removed by oxygen plasma ashing or wet stripping. In the subsequent process, metal silicide can be optionally formed on the gate 125a, 125b and/or source/drain 170a, 170b to increase the operation speed of MOS transistors. Since the method of forming metal silicide is well known by persons skilled the semiconductor process, the detailed description of the method for forming metal silicide is thus omitted here.

According to the embodiment described above, the original photoresists used to define the gates are also used as ion implantation masks to form lightly doped region having deep junction depth (i.e. the double-diffused drain) in the high-voltage area to effectively protect the structure of the gate and the gate dielectric layer. Moreover, the photoresist as the ion implantation masks can be easily removed by general methods without damaging the structure of the shallow trench isolation. Therefore, the process described above can be easily integrated with salicide process, a self-aligned process for fabricating metal silicide.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of fabricating a high-voltage MOS having double-diffused drain (DDD), the method comprising:
sequentially forming a dielectric layer and a conductive layer on a substrate;
forming a patterned photoresist on the conductive layer;
etching the exposed conductive layer and the dielectric layer thereunder to form a gate and a gate dielectric layer on the substrate;
stabilizing the structure of the photoresist;
forming lightly-doped regions having deep junctions in the substrate by using the gate as an implantation mask to implant the substrate;
removing the photoresist;
forming spacers on sidewalls of the gate; and
forming heavily-doped regions in the substrate by using the gate and the spacers as implantation masks to implant the substrate, wherein the junction depth of the heavily-doped regions is shallower than the junction depth of the lightly-doped regions, and the dopant concentration of the heavily-doped regions is larger than the dopant concentration of the lightly-doped regions.

2. The method of claim 1, wherein the photoresist is stabilized by hard baking.

3. The method of claim 1, wherein the hard baking comprises heating or UV illuminating.

4. The method of claim 1, wherein a thickness of the photoresist is larger than 8000 Å.

5. The method of claim 1, wherein the conductive layer comprises polysilicon or metal silicide.

6. The method of claim 1, wherein the photoresist is removed by oxygen plasma ashing or wet striping.

7. An integration method of fabricating low-voltage MOS and high-voltage MOS having double-diffused drain, the method comprising:
sequentially forming a dielectric layer and a conductive layer on a substrate having a low-voltage area and a high-voltage area;
forming at least two first photoresists on the conductive layer;
etching the exposed conductive layer and the dielectric layer thereunder to respectively form a first gate and a first gate dielectric layer on the low-voltage area and a second gate and a second dielectric layer on the high-voltage area;
stabilizing the structure of the first photoresist;
forming a patterned second photoresist on the low-voltage area;
implanting the high-voltage area of the substrate to form two lightly-doped regions having deep junction depths on two sides of the second gate;
removing the second photoresist;
implanting the substrate to form lightly-doped drains on two sides of the first gate;
removing the first photoresists;
forming plural spacers on sidewalls of the first gate and the second gate; and
implanting the substrate to form source and drain on outer sides of the spacers.

8. The method of claim 7, wherein the first photoresists are stabilized by hard baking.

9. The method of claim 8, wherein the hard baking is performed by heating or illuminating UV light.

10. The method of claim 7, wherein the thickness of the first photoresists is greater than 8000 Å.

11. The method of claim 7, wherein the conductive layer comprises polysilicon or metal silicide.

12. The method of claim 7, wherein the first photoresists are removed by oxygen plasma ashing or wet stripping.
